(19) United States
(12) Patent Application Publication
(10) Pub. No.: US 2026/0352094 A1
(43) Pub. Date: Nov. 5, 2026

(54) POWER ELECTRONIC CIRCUITS AND MODULATION METHODS FOR EMI ERADICATION AT SOURCE

(71) Applicant: Portland State University, Portland, OR (US)

(72) Inventor: Mahima Gupta, Portland, OR (US)

(21) Appl. No.: 19/118,739

(22) PCT Filed: Oct. 6, 2023
(86) PCT No.: PCT/US2023/076269

§ 371 Date: Apr. 4, 2025

Related U.S. Application Data
(60) Provisional application No. 63/378,800, filed on Oct. 7, 2022.

(51) Int. Cl. H02M 1/44; H02M 3/156; H02M 7/537

(52) U.S. Cl. CPC H02M 1/44; H02M 3/156; H02M 7/537

(57) ABSTRACT

A power electronic circuit can include: a first switch; a second switch; and a capacitor, wherein a switch throw of the first switch is configured to be electrically coupled to a first terminal of the capacitor and a switch throw of the second switch is configured to be electrically coupled to a second terminal of the capacitor, wherein the first and second switches are configured to connect to the capacitor periodically every switching cycle.

### CROSS REFERENCE TO RELATED APPLICATIONS

This application claims priority to U.S. Provisional Application No. 63/378,800, entitled “POWER ELECTRONIC CIRCUITS AND MODULATION METHODS FOR EMI ERADICATION AT SOURCE,” and filed Oct. 7, 2022, the entire contents of which are hereby incorporated by reference for all purposes.

### FIELD

The disclosure relates to power electronics, and more specifically to circuitry for reducing electromagnetic interference (EMI).

### BACKGROUND AND SUMMARY

Power electronic converters (PECs) enable power transfer from energy sources to energy loads by reconciling their differences in voltages, currents, frequency of operation while facilitating DC-DC, DC-AC and AC-AC conversion. The forming elements of these PECs are semiconductor switches and energy storage elements. While several technological developments have permitted widespread use of PECs, the discipline faces several challenges before their further adoption.

In contrast to linear electronics, power electronics feature switching operations which result in inherent electromagnetic interference issues victimizing energy source and loads. Embodiments of the disclosed technology generally include an EMI Eradicator (EMI-E) circuitry approach to address this challenge and enable further electrification.

Embodiments of the disclosed EMI Eradicator (EMI-E) circuitry quenches EMI noise at the source (i.e., the transistor switch) while reducing system losses. EMI-E is integrated at the mid-point of classical half-bridge PECs to smooth the high dv/dt noisy node into tunable edges characteristic of the system specifications. This approach advantageously addresses the electromagnetic noise challenges of power electronic converter circuits inherent to all power electronic converters, in L/M/HV applications. It will be appreciated that the disclosed methodologies can be applied to a variety of applications such as EVs, aviation, industry electrification, consumer goods and so on.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The disclosure may be better understood from reading the following description of non-limiting embodiments, with reference to the attached drawings.

FIG. 1 illustrates an example of coupling paths due to DC/DC and DC/AC converters connecting a hybrid PV+Battery power plant to the grid 100.

FIG. 2 illustrates example circuit schematics of a primitive PEC 200, a switch realization of a SPDT switch using MOSFETs 205, and a typical switching voltage waveform for an EMI source 210.

FIG. 3 illustrates an example circuit schematic of a simple DC-DC converter with subscript S and L denoting source and load respectively, and where traces 302, 304 highlight EMI eradicator circuitry 300 according to certain embodiments of the disclosed technology.

FIG. 4A illustrates example analytical waveforms of S and L switching signals, capacitor voltages, bottom load switch voltage and current waveform for a conventional modulation method 400.

FIG. 4B illustrates example analytical waveforms of S and L switching signals, capacitor voltages, bottom load switch, and EMI eradicator load switch for a modulation method 405 according to certain embodiments of the disclosed technology.

FIG. 5 illustrates an example 500 of a Fourier Spectrum of switching voltage with a conventional PWM and turn-on/off time of 100 ns (502) and a PWM method with EMI eradicator time of 1 μs (504) according to certain embodiments of the disclosed technology.

FIG. 6A illustrates a typical MOSFET switching loss for a conventional modulation method 600.

FIG. 6B illustrates a MOSFET switching loss for a modulation method 605 according to certain embodiments of the disclosed technology.

FIG. 7 is a graph 700 illustrating an example of experimental data of a tuned switching voltage with EMI-E circuitry according to certain embodiments of the disclosed technology compared against a conventional PWM approach.

FIG. 8 illustrates an example of monolithic EMI eradicator circuitry with switch realizations for bi-directional power flow and universal buck/boost operation 800 according to certain embodiments of the disclosed technology.

FIG. 9 illustrates an example of a grid connected converter application 900 according to certain embodiments of the disclosed technology.

FIG. 10 illustrates an example circuit schematic of a power electronic converter 1000 where the circuitry between the two Pole points features the EMI-E circuitry and the circuit is capable of bidirectional power flow and step-up/down operation. In the example, the converter 1000 includes bidirectional transistors annotated as S⁰_{S} and S^{O}_{L} where subscript S and L denote source and load, respectively.

FIG. 11 illustrates an example of a conventional modulation strategy with boost-mode of operation 1100.

FIG. 12 illustrates an example of a modulation strategy with buck-mode of operation 1200 in accordance with embodiments of the disclosed technology.

FIG. 13 illustrates an example of three different EMI-E switch configurations 1300, 1305, 1310 in accordance with embodiments of the disclosed technology.

FIGS. 14A-B illustrate an example of a modulation strategy with buck-mode of operation with bidirectional switches operated with different gate driver signals in accordance with embodiments of the disclosed technology. FIG. 14A illustrates a simple gate signal implementation at S⁰_{L} 1400 and FIG. 14 B illustrates a flexible gate signal implementation at S⁰_{L} 1405.

FIG. 15 illustrates an example of a modulation strategy with boost-mode of operation 1500 in accordance with embodiments of the disclosed technology.

FIG. 16 illustrates an example of experimental data confirming feasibility of the disclosed approach while illustrating reduced EMI noise issues and minimized switching losses 1600.

FIG. 17 illustrates an example of a circuit schematic for DC-AC power conversion 1700.

FIG. 18 illustrates an example of a space vector diagram for an AC inverter operation 1800 in accordance with certain embodiments of the disclosed technology.

FIG. 19 illustrates an example of switching waveforms for DC-AC conversion for a certain sector of operation 1900.

FIG. 20 illustrates an example of a Fourier Spectrum at inverter terminals with conventional approaches and disclosed approaches 2000.

FIG. 21 illustrates an example of switching voltage transient at load terminals with conventional approaches and disclosed approaches 2100.

FIG. 22 illustrates an example of a switch turn-off transition with conventional approaches and disclosed approaches 2200.

FIG. 23 illustrates an example 2300 of experimental waveforms of the turn-on interval switch voltage with conventional approaches (2301) and disclosed PWM approaches (2302). FIG. 23 also illustrates an example 2305 of experimental waveforms of the turn-on interval pole current with conventional approaches (2306) and disclosed PWM approaches (2307).

FIG. 24 illustrates an example 2400 of experimental waveforms of the turn-off interval switch voltage with conventional approaches (2401) and disclosed PWM approaches (2402). FIG. 24 also illustrates an example 2405 of experimental waveforms of the turn-off interval pole current with conventional approaches (2406) and disclosed PWM approaches (2407).

FIG. 25 illustrates an example 2500 of the frequency-domain Fourier spectrum of the switch voltage for conventional approaches (2501) and disclosed approaches (2502).

FIG. 26 illustrates an example 2600 of the frequency-domain Fourier spectrum of the pole current (of FIGS. 23-24) for conventional approaches (2601) and disclosed approaches (2602).

FIG. 27 illustrates experimental results 2700 that confirm the analytical results illustrated by FIG. 6B.

### DETAILED DESCRIPTION

Development of high-voltage rated (>10 kV) and fast switching (<0.1 μs) WBG/UWBG devices is considered essential for H/MV power electronic applications including the power grid. The dv/dt rate of such device applications will go beyond 100 kV/μs. Even a small parasitic 10 pF capacitor, for example between the transistor and heatsinks, can result in 1A leakage current, easily exceeding power quality standard limits.

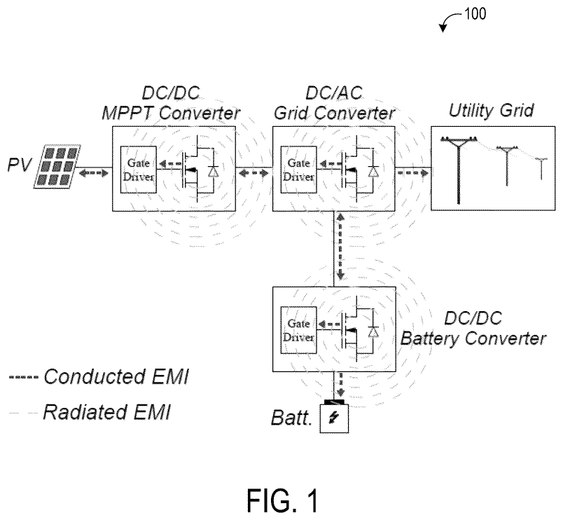

FIG. 1 illustrates an example of coupling paths due to DC/DC and DC/AC converters connecting a hybrid PV+Battery power plant to the grid 100. This block diagram highlights the transistor device as the EMI noise source. The switching action of the transistor device can result in conducted (dashed lines) and radiated (dashed circles) EMI issues victimizing the system including the PV panels, batteries and the utility grid.

Embodiments of the disclosed EMI Eradicator (EMI-E) circuitry advantageously provide ultra-fast switching of transistor devices while simultaneously reducing overall switch losses and EMI issues.

Power electronic circuits (PECs) generally include semiconductor switches (SS) that can enable switch-mode power conversion. PECs also generally include energy storage (ES) elements, such as capacitors and inductors. ES elements can smoothen the switching voltage and current waveforms that are characteristic of switching circuits. Together, SS & ES form fundamental building blocks of PECs.

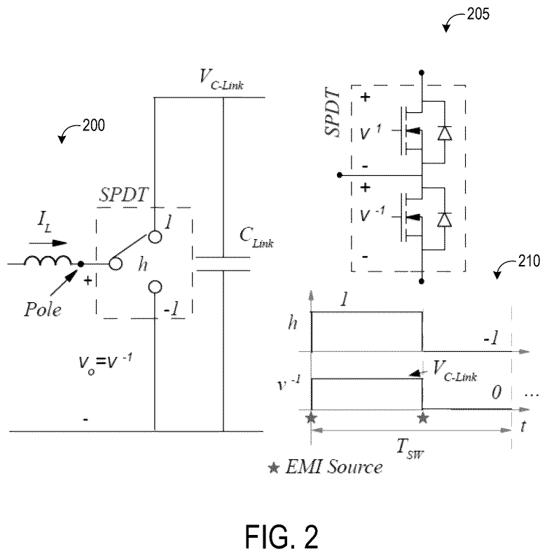

FIG. 2 illustrates examples circuit schematics of a primitive PEC 200, a switch realization of a single-pole double-throw (SPDT) switch using MOSFETs 205, and a typical switching voltage waveform for an EMI source 210.

Typically, the SPDT switch is realized using two semiconductor switches, illustrated using MOSFETs 205. Control of the SS over a high-frequency switching cycle T_{SW} is achieved using modulation approaches such as by adjusting the pulse width of the switching function (h) of the SPDT or pulse-width modulation (PWM). The waveform 210 illustrates a modulation approach for the primitive converter where, h=1 and h=−1 result in turn-on of the top switch and the bottom switch, respectively. In the example, v 1=v_{O} refers to the switch “−1” voltage which is also the output voltage. While waveforms h and v_{O} can be mapped to each other, the output pole voltage v_{O} switches between 0V and the capacitor voltage V_{C}-Link, which may be hundreds to thousands of volts (>100V to several kV) based on applications resulting in electromagnetic interference (EMI) due to high dv/dt rates.

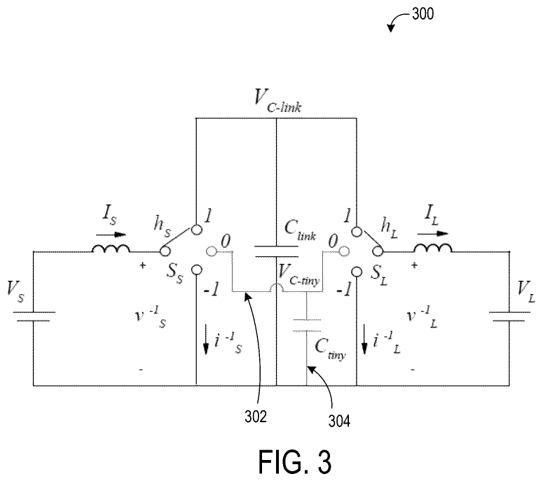

FIG. 3 illustrates an example circuit schematic of a simple DC-DC converter with subscript S and L denoting source and load respectively, and where traces 302, 304 highlight EMI eradicator circuitry 300 according to certain embodiments of the disclosed technology. In the example, two primitive PECs are cascaded and subscripts S & L denote source and load, respectively, although bidirectional power flow is feasible.

For the power transfer between the source and the load, the source and load SPDT switches, S_{S} and S_{L}, connect to the DC capacitor, C_{Link}, periodically every switching cycle, T_{SW}. The width of the source and the load switching functions, h_{S} and h_{L}, determine the voltage and current transfer relationships between the source and the load.

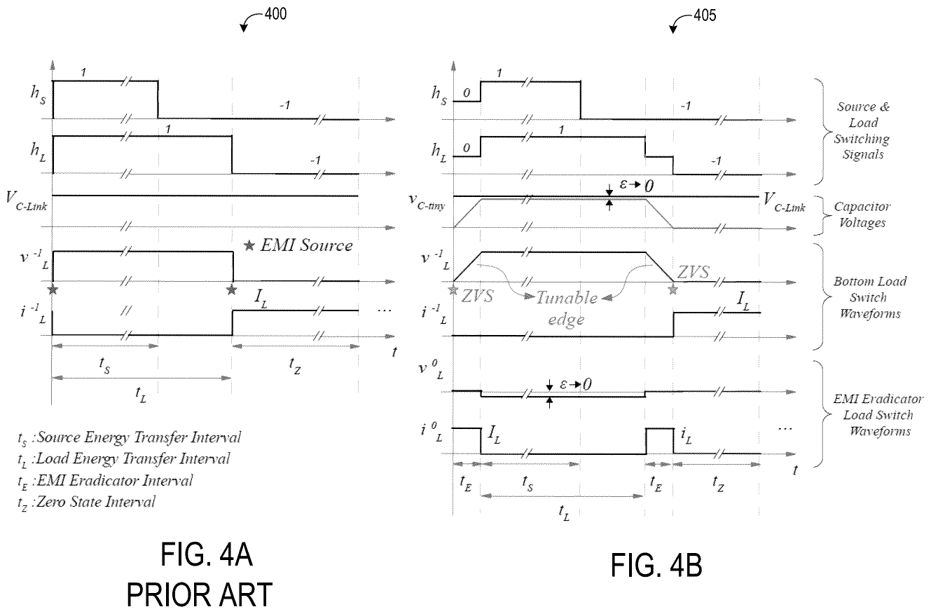

FIG. 4A illustrates example analytical waveforms of S and L switching signals, capacitor voltages, bottom load switch for a conventional modulation method 400. The example 400 includes waveforms typical of step-up (boost) voltage mode of operation. Time intervals t_{S} and t_{L} characterize the power transfer operation. With the disclosed PWM method, the power transfer switching methodology is unaffected; however, the disclosed method can employ the EMI eradicator circuitry, e.g., traces 302, 304, to tune the EMI source edges, i.e., the high dv/dt rate turn-on and turn-off transients, in order to suppress the EMI issues. It will be appreciated that the switch turn-on and turn-off times are not increased which will result in increased switching losses. In contrast, the switches now operate under zero-voltage-switching (ZVS) resulting in minimal switching losses.

FIG. 4B illustrates example analytical waveforms of S and L switching signals, capacitor voltages, bottom load switch, and EMI eradicator load switch for a modulation method 405 according to certain embodiments of the disclosed technology. A contrasting feature of the disclosed modulation method begins with the top two waveforms of the switching functions which have an additional state, annotated as “0” state. During the “0”, the EMI Eradicator (EMI-E) circuitry is activated and utilizes a tiny capacitor, C_{tiny}.

Conventional capacitors such as C_{Link} have values in the range of milli-farads to tens of milli-farads. Such capacitors, which are physically large and bulky, are typically used as an energy storage device to maintain stiffness at the DC side, e.g., nearly constant voltage. As used herein, the term tiny capacitor generally refers to a capacitor that is significantly smaller than conventional capacitors such as C_{Link}, e.g., at least 1,000 times smaller, whose value is in the range of nano-farads to pico-farads; in certain applications, the value of the tiny capacitor may be fractional micro-farad. In some aspects, the tiny capacitor may be monolithically integrated with EMI-E circuitry such as an EMI-E switch.

The EMI Eradicator circuitry may use the tiny capacitor to tune the dv/dt rates during turn-on and turn-off. For example, during the beginning of the switching cycle, both source and load connect to the tiny capacitor. As the tiny capacitor charges, the switch pole voltages rise with V_{C-tiny} which is tuned and designed per system requirements. Similar analysis can be extended for other transitions. During the turn-on and turn-off switching instants, C_{tiny} can be charged and discharged to shape the PEC switching waveforms into trapezoidal shapes instead of conventional rectangular waveforms as illustrated by FIG. 4A where, t_{E} is the tunable EMI eradicator interval.

The disclosed EMI eradicator circuitry permits the tuning of high dv/dt edges of switching power electronic converters. That is, the switching waveforms are shaped to be trapezoidal where the rising and falling edges of the switched waveform are designed to eradicate EMI issues. Equation (1) below characterizes the composition of a typical switching waveform from PEC:

$${v}_{L}^{- 1} = {\underbrace{{dV}_{C - Link}}}_{power transfer} + {\sum }_{n = 1}^{∞} 2 {dV}_{C - Link} \vert \frac{sin ( n π d )}{n π d} \vert {\underbrace{\vert \frac{sin ( n π {t}_{t} / {T}_{SW} )}{n π {t}_{t} / {T}_{SW}} \vert}}_{{Conv . : {t}_{t} = rise / fall time}_{Prop . : {t}_{t} = eradicator Interval}} cos ( n ω t + ϕ ) \qquad ( 1 )$$

In addition to the power transfer component (featuring power transfer duty ratio, d), the waveform comprises high-frequency harmonics with the amplitude determined by the turn-on/off times, where tₜ=tᵣᵢₛₑ, t_{fall}. Faster switches with small tᵣᵢₛₑ, t_{fall} values feature higher harmonic content, resulting in higher EMI issues.

This equation can be used to characterize the composition of a typical switching waveform with the EMI-E. However, with EMI-E, the amplitude of the high-frequency harmonics are tuned and determined using the EMI-E time interval, t_{E}.

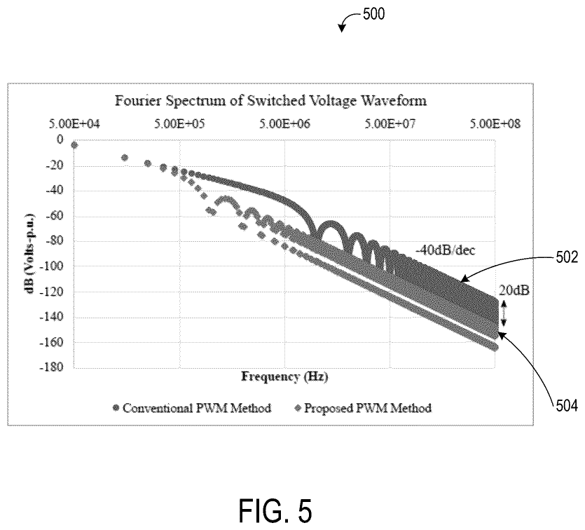

FIG. 5 illustrates a Fourier Spectrum of switching voltage with a conventional PWM and turn-on/off time of 100 ns (502) and a PWM method with EMI-time t_{E} of 1 μs (504) 500 according to certain embodiments of the disclosed technology. In the example, the EMI noise is reduced by 20 dB (an order of magnitude in linear scale).

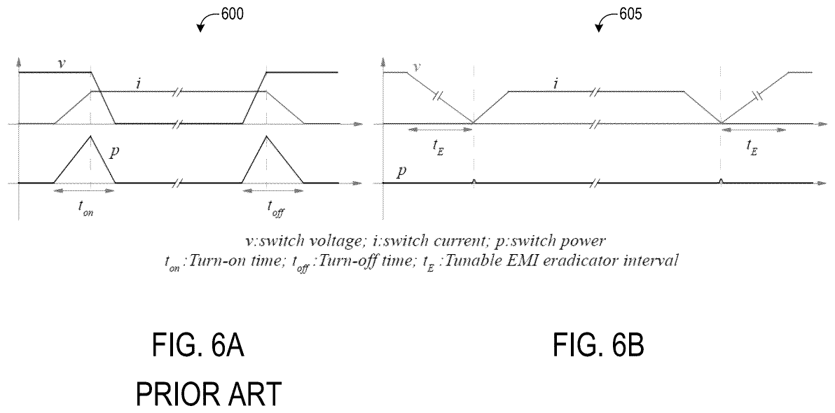

As noted above, FIG. 4 illustrates simplified switching waveforms where the switching action is assumed to be instantaneous. FIGS. 6A-B focus on turn-on and turn-off time intervals.

FIG. 6A illustrates a typical MOSFET switching loss for a conventional modulation method 600, i.e., voltage and current waveforms during turn-on and turn-off with a conventional PWM. The switching power loss is characterized by Equation (2)

$$P = \frac{1}{{T}_{SW}} {\int }_{0}^{{T}_{SW}} v ( t ) i ( t ) dt \qquad ( 2 )$$

where v(t) and i(t) represent switch voltage and current waveforms, respectively. Conventional switching waveforms result in overlap between the switch voltage and current waveforms during switching and, hence, switching power loss.

In contrast, with the disclosed approach, the switch connects to the EMI-E circuitry before turning-on and after turning-off resulting in zero-voltage or near zero-voltage, e.g., approximately 1% of peak voltage, during switching instants. Consequently, the proposed PWM method enables zero-voltage switching (ZVS) and elimination of switching loss, as highlighted in FIG. 6B, which illustrates a MOSFET switching loss for a modulation method 605 according to certain embodiments of the disclosed technology.

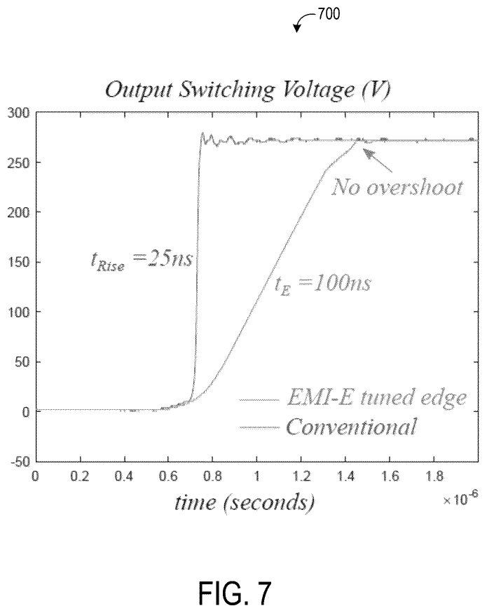

FIG. 7 illustrates an example of experimental data of a tuned switching voltage with EMI-E circuitry according to certain embodiments of the disclosed technology compared against a conventional PWM approach 700.

It will be appreciated that the disclosed EMI-E methodology can be extended to other DC-DC, DC-AC, AC-AC power converter topologies.

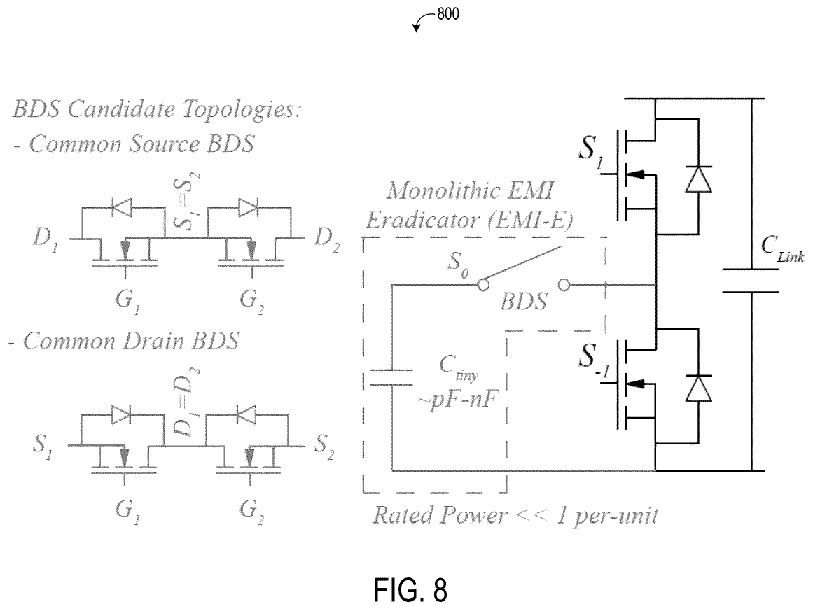

FIG. 8 illustrates an example of monolithic EMI eradicator circuitry with switch realizations for bi-directional power flow and universal buck/boost operation 800 according to certain embodiments of the disclosed technology. In the example, the tiny capacitance design of the EMI circuitry permits monolithic integration with switches to minimize second order effects such as parasitic inductances and enhance circuit design simplicity.

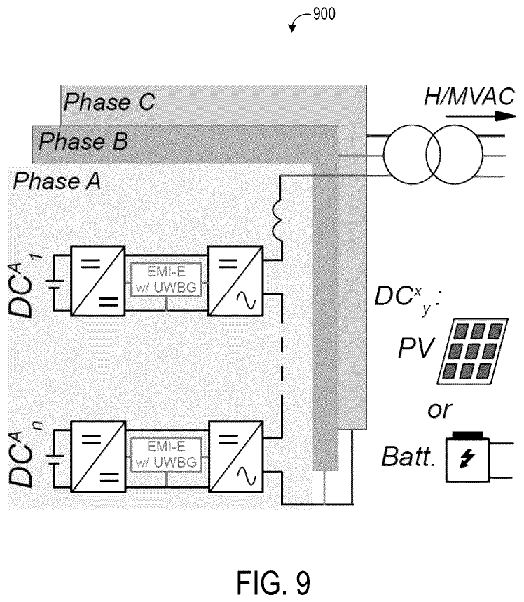

FIG. 9 illustrates an example of a grid connected converter application 900 according to certain embodiments of the disclosed technology. The example 900 includes a grid connected DC/AC modular power converter topology connecting photovoltaic (PV) or battery energy storage (BESS) systems to the AC grid, with the EMI Eradicator (EMI-E) circuitry connection per module featuring the monolithically integrated bidirectional UWBG devices. The disclosed approach can be applied in a wide variety of applications such as electric vehicles (EVs), aviation, industry electrification, and consumer goods, for example.

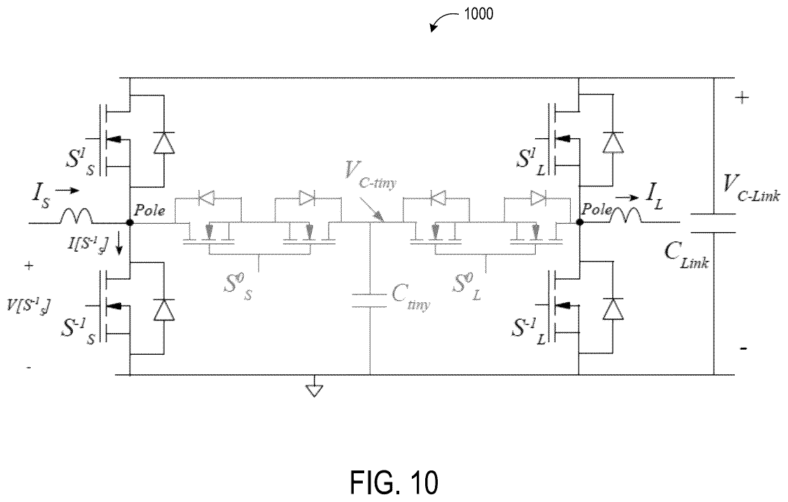

FIG. 10 illustrates an example circuit schematic of a power electronic converter 1000 where the traces between the two Pole points feature the EMI-E circuitry and the circuit is capable of bidirectional power flow and step-up/down operation. In the example, the converter 1000 includes bidirectional transistors annotated as S⁰_{S} and S⁰_{L} where subscript S and L denote source and load, respectively.

As described herein, switching functions (denoted using h) represent the position of the single-pole double-throw (SPDT) switch. When the pole connects to the top throw, h=1; when the pole connects to the bottom throw, h=−1. The SPDT switch is realized using two transistors where the top and bottom throw are replaced with two controllable devices. These devices are controlled using their gate terminals (i.e., by defining gate signals denoted using G). When the transistor is controlled to turn-on, G=1, otherwise, G=0.

The poles of the SPDT switches connect to a current-stiff port i.e., the inductors. The throws connect to a voltage-stiff port i.e., the capacitor (C_{Link}). The pole connects to the top or the bottom throw when switches S¹ₓ or S⁻¹ₓ turn-on (x=S, L). During the transition from S¹ₓ→S⁻¹ₓ or from S⁻¹ₓ→S¹ₓ, proper gate-signals must be provided to the switches to prevent shoot-throughs or over-voltages. If the gate-signals overlap (i.e., there is an overlap time between the top and the bottom switch gate-signals G[S¹]=G[S⁻¹]=1), both switches will turn-on and short the capacitor (C_{Link}) resulting in an undesirable shoot-through scenario.

To avoid this scenario, a dead-time (DT) is provided between the gate signals of the top and the bottom device gate signals (i.e., G[S¹]=G[S⁻¹]=0 for the dead-time interval during the transition). At first glance, it may be concluded that the current-stiff inductor will be open-circuited resulting in over-voltages; however, in this scenario, the presence of anti-parallel diode, also illustrated in FIG. 10, becomes significant (e.g., the diode may be an external device or the body-diode of a MOSFET or an IGBT).

A diode is an uncontrolled device (i.e., no gate terminal) and turns on/off based on circuit operation. Considering the transition at the source-side, due to the current direction into the pole, the diode of the top device can turn-on and conduct when the bottom device gate-signal is turned-off and dead-time (DT) will not lead to current open-circuit scenario; the current will find a path through the top diode. Similarly, considering the transition at the load-side, due to the current direction out of the pole, the diode of the bottom device can conduct when the top device gate-signal is turned-off. Hence, it is very common to have dead-times between the gate signals of such converter circuits.

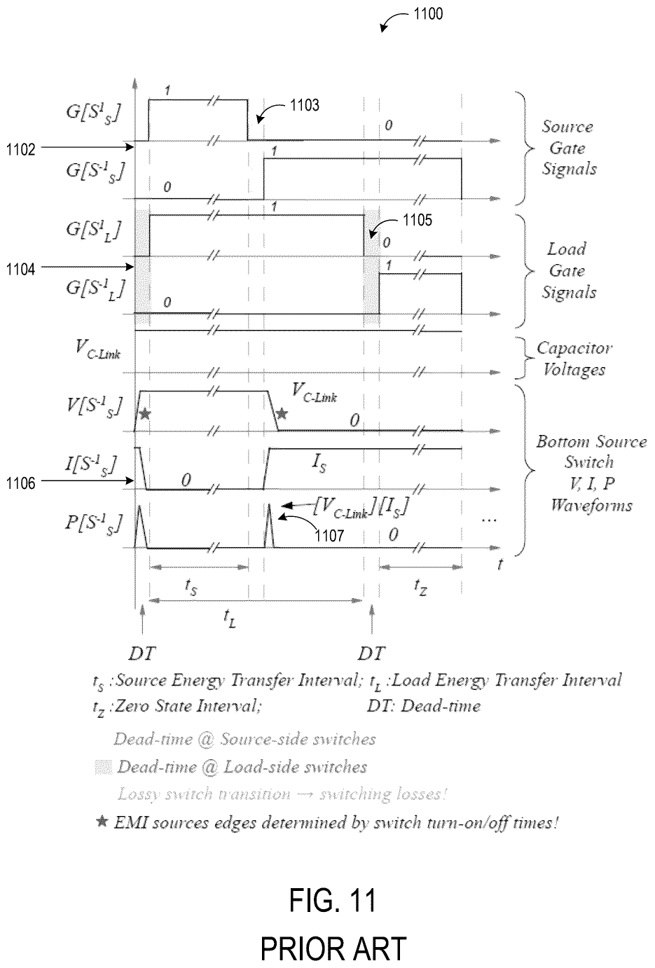

FIG. 11 illustrates an example of a conventional modulation strategy with boost-mode of operation 1100. The example illustrates the dead-time windows for the source and the load gate signals using windows 1102/1103 and 1104/1105, respectively.

Focusing on the power transfer operation, for the conventional case, the source and the load side gate signals may or may not be synchronized i.e., they may be operating at a different switching frequency or may not be aligned. For simplicity, FIG. 11 illustrates the case when the source/load signals are synchronized. The last three waveforms of the figure illustrate the voltage (V), current (I) and power (P) waveforms of the source-side bottom switch and can be mapped to the source-side gate signals (i.e., top two waveforms, G[S¹] and G[S⁻¹]). When the gate signal G[S⁻¹]=1, the bottom switch conducts current I_{S} and blocks 0V. When the gate signal G[S⁻¹]=0, the switch conducts 0 A and blocks the de voltage V_{C}-Link.

Focusing on the source-side, during the dead-time, the transition occurs between the top device (i.e., anti-parallel diode) and the bottom device; the diode doesn't start to carry current until the voltage across it is zero. Using this basic idea, the transition waveforms can be drawn. During the first DT (window 1106), the voltage across the bottom switch begins to drop as soon as G[S⁻¹]=0. However, the bottom switch continues to carry current I_{S}, resulting in power losses (P[S⁻¹]=0).

Drawing a parallel for the other transition, the diode doesn't start to block any voltage until the current is zero. Consequently, during the second DT (window 1107), the voltage across the bottom switch begins to drop when the entire current I_{S} transfers from the top diode to the bottom switch, again resulting in switch power losses (P[S⁻¹]=0). The losses during these transitions are commonly known as switching losses. With the disclosed approach, switching power loss can be eliminated.

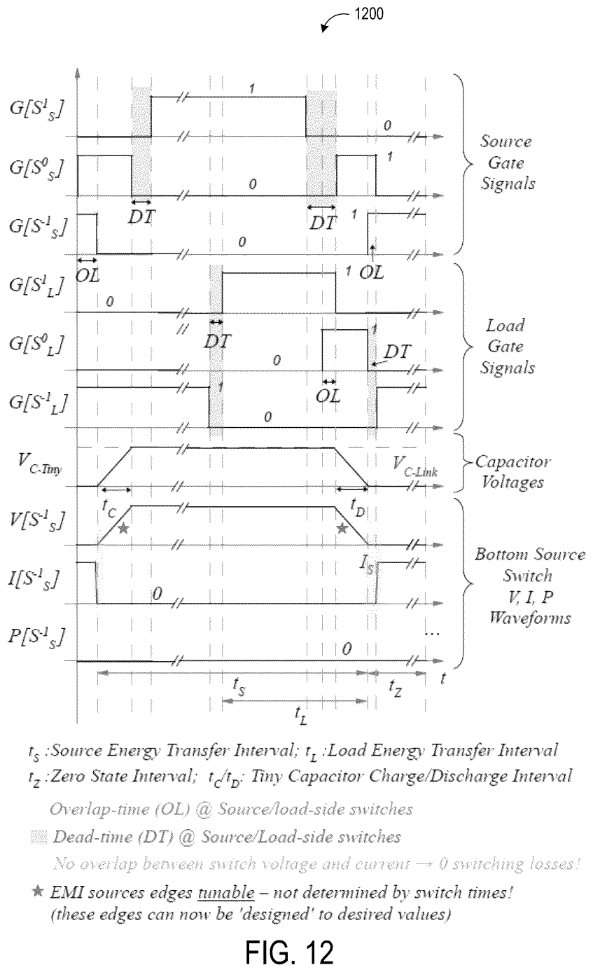

FIG. 12 illustrates an example of a modulation strategy with buck-mode (e.g., voltage step-down between source and load) of operation 1200 in accordance with embodiments of the disclosed technology.

The transition of h_{S} from −1→0→1 is herein referred to as Transition A, and the transition of h_{S} & h_{L} from 1→0→−1 is referred to herein as Transition B. These translate to when gate signals

$$G [ {S}_{x}^{1} ] , G [ {S}_{x}^{0} ] , G [ {S}_{x}^{- 1} ]$$

change state between 0 and 1 (x=S, L).

During Transition A, the switch-side pole voltage is tuned i.e., h_{S}: −1→0→1. Focusing on the top three waveforms of FIG. 12,

$$G [ {S}_{S}^{1} ] , G [ {S}_{S}^{0} ] , G [ {S}_{S}^{- 1} ] ,$$

the transition occurs from the bottom transistor to the EMI-E switch

$$( {S}_{S}^{0} )$$

to the top diode (due to source current direction into the pole).

As soon as the gate signal

$$G [ {S}_{S}^{- 1} ]$$

goes to zero, the stiff current will turn-on the top diode (similar to the conventional case) if the EMI-E switch is not activated. In order to avoid this conventional scenario and tune the dv/dt edge, an overlap time is introduced between

$$G [ {S}_{S}^{- 1} ] and G [ {S}_{S}^{0} ] .$$

As soon as

$$G [ {S}_{S}^{- 1} ]$$

is made zero, EMI-switch

$${S}_{S}^{0}$$

takes over the current I_{S} and begins to charge the tiny capacitor. The top switch diode cannot conduct because it is reverse-biased (the voltage across the diode is (V_{C-Link}−V_{C-tiny})>0). The charge interval t_{C} is tuned to charge the tiny capacitor to V_{C-Link} after which the top switch diode takes over. The top switch can now be turned-on after a DT (the top switch is already “on” since the diode is conducting). Note that the rate of rise of the rising-edge of the tiny-capacitor is tuned by the source current and the capacitor value.

During Transition B, both the switch-side and the load-side pole voltages are tuned i.e., h_{S}&h_{L}: 1→0→−1. Focusing on the top six waveforms of FIG. 12,

$$G [ {S}_{S}^{1} ] , G [ {S}_{S}^{0} ] , G [ {S}_{S}^{- 1} ] and G [ {S}_{L}^{1} ] , G [ {S}_{L}^{0} ] , G [ {S}_{L}^{- 1} ] ,$$

the transition at the source occurs from the top diode to the EMI-E switch

$${S}_{S}^{0}$$

to the bottom switch and the transition at the load occurs from the top switch to the EMI-E switch

$${S}_{L}^{0}$$

to the bottom diode. Due to the buck operation, I_{S}<I_{L}.

At the source, since the top diode conducts, the top switch gate signal can be turned-off

$$( G [ {S}_{S}^{1} ] = 0 )$$

and the current will still continue to flow as-is. Next, the load-side EMI-E switch is activated to turn-on

$$( G [ {S}_{L}^{0} ] = 1 )$$

prior to the turning-off the top switch—otherwise, the bottom diode will turn-on similar to the conventional case eliminating the possibility of tuning the dv/dt edge. Hence,

$$G [ {S}_{L}^{0} ] and G [ {S}_{L}^{1} ]$$

have an overlap interval. Next, once

$$G [ {S}_{L}^{1} ] = 0 ,$$

the EMI-E load switch takes over and begins to discharge the tiny capacitor. The source-side EMI-E switch can be timed to turn-on at this instant for current transition from top switch diode to the EMI-E switch. Hence, the discharge interval t_{D} begins to discharge the tiny capacitor to zero consequently tuning the dv/dt edges.

After the discharge is complete, at the source-side,

$$G [ {S}_{S}^{0} ]$$

can continue to be “on” and have a small safety overlap interval with

$$G [ {S}_{S}^{- 1} ]$$

to prevent any dv/dt rates due miscalculations in t_{D} tuning interval. At the load-side,

$$G [ {S}_{L}^{0} ]$$

can have a dead-time interval with

$$G [ {S}_{L}^{- 1} ]$$

since the diode can naturally take over once the tiny capacitor is discharged.

The bottom three waveforms of FIG. 12 illustrate voltage, current and power waveforms of the source-side bottom switch. In contrast to the conventional case, the dv/dt edges of the voltage waveform are tuned using the EMI-circuitry. Hence, they can be designed (to reduce EMI noise) and are not determined by the inherent and fast rising and falling edges of the transistor devices. Further, the designed modulation strategy features near zero voltage when the current rises/falls. Hence, the switching losses are close to zero, as illustrated by the bottom waveform.

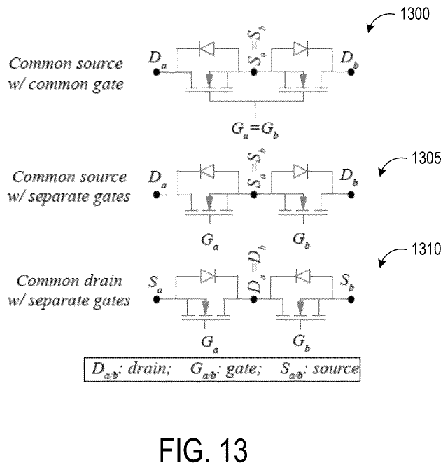

FIG. 13 illustrates an example of three different EMI-E switch configurations 1300, 1305, 1310 in accordance with embodiments of the disclosed technology.

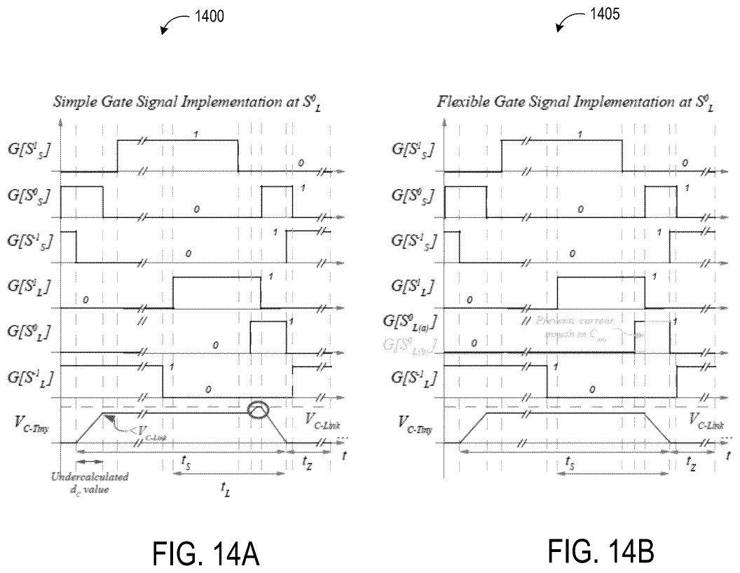

FIGS. 14A-B illustrate an example of a modulation strategy with buck-mode of operation with bidirectional switches operated with different gate driver signals in accordance with embodiments of the disclosed technology. FIG. 14A illustrates a simple gate signal implementation at S⁰_{L} 1400 and FIG. 14 B illustrates a flexible gate signal implementation at S⁰_{L} 1405.

With shared gate terminals, two devices can be turned-on/off together; however, further optimizations are possible particularly when the tuned charge and discharge intervals do not lead to V_{C-tiny} being close to V_{C-Link}. In this scenario, the availability of separate gate signals can be exploited. One such scenario is illustrated by FIGS. 14A-B. Here, V_{C-tiny} charges to a value lower than V_{C-Link}. As illustrated in FIG. 14A, if the gate terminals of the two switches of

$${S}_{S}^{0}$$

are tied together, C_{tiny} will see an inrush in current and charge-up to V_{C-Link}. With flexibility in gate terminals, the turn-on of one switch of

$${S}_{S}^{0}$$

can be delayed to prevent inrush current flow from C_{Link} to C_{tiny} as illustrated by FIG. 14B.

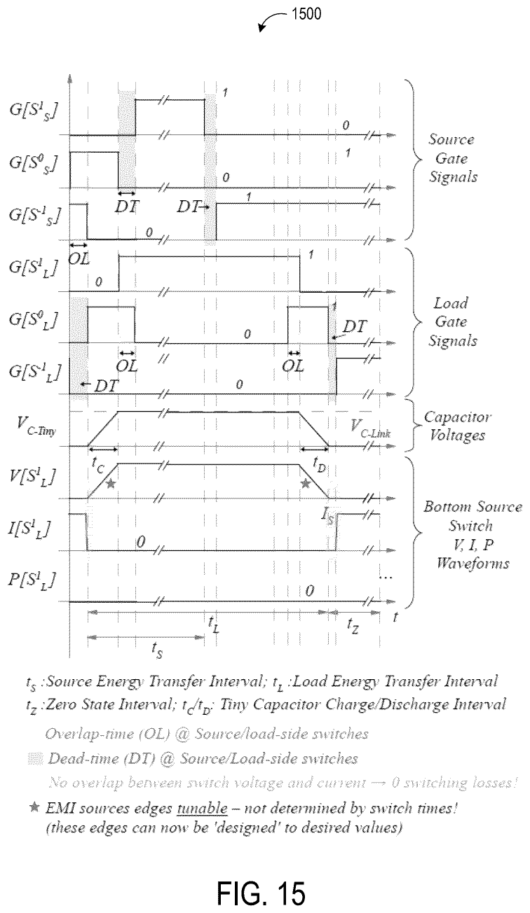

FIG. 15 illustrates an example of a modulation strategy with boost-mode of operation 1500 in accordance with embodiments of the disclosed technology. The example 1500 includes waveforms detailing zero-voltage switching (ZVS) operation resulting in zero switching losses.

The transition of h_{S} & h_{L} from −1→0→1 is referred to herein as Transition C, and the transition of h_{L} from 1→0→−1 is referred to herein as Transition D. These translate to when gate signals

$$G [ {S}_{x}^{1} ] , G [ {S}_{x}^{0} ] , G [ {S}_{x}^{- 1} ]$$

change state between 0 and 1 (x=S, L).

During Transition C, both the switch-side and the load-side pole voltages are tuned i.e., h_{S}&h_{L}: −1→0→1. Focusing on the top six waveforms of FIG. 15.

$$G [ {S}_{S}^{1} ] , G [ {S}_{S}^{0} ] , G [ {S}_{S}^{- 1} ] and G [ {S}_{L}^{1} ] , G [ {S}_{L}^{0} ] , G [ {S}_{L}^{- 1} ] ,$$

the transition at the source occurs from the bottom switch to the EMI-E switch

$${S}_{S}^{0}$$

to the top diode and the transition at the load occurs from the bottom diode to the EMI-E switch

$${S}_{L}^{0}$$

to the top switch. Due to boost operation, I_{S}>I_{L}.

At the load, since the bottom diode conducts, the bottom switch gate signal can be turned-off

$$( G [ {S}_{L}^{- 1} ] = 0 )$$

and the current will still continue to flow as-is. Simultaneously, at the source, since the bottom switch conducts, the EMI-E switch gate signal can be turned-on

$$( G [ {S}_{L}^{- 1} ] = 1 ) .$$

Again, the current will still continue to flow as-is since the bottom switch is still on

$$( G [ {S}_{L}^{- 1} ] = 1 ) .$$

### Hence,

$$G [ {S}_{S}^{0} ] and G [ {S}_{S}^{- 1} ]$$

have an overlap interval.

Next, since the source-side EMI-E switch is already activated to turn-on, the bottom switch can be turned-off

$$( G [ {S}_{S}^{- 1} ] = 0 ) .$$

This will begin the charge interval t_{C} for the tiny capacitor. Simultaneously, the load-side EMI-E switch can be turned-on,

$$( G [ {S}_{L}^{0} ] = 1 ) .$$

Since the tiny-capacitor charges, the bottom device diode will become reverse-biased and turn-off. Once the voltage across the tiny capacitor reaches V_{C-Link}, the source-side top diode will take over and begin to conduct. Hence.

$$G [ {S}_{S}^{0} ] and G [ {S}_{S}^{1} ]$$

can nave a dead-time. At the load-side,

$$G [ {S}_{L}^{0} ] and G [ {S}_{L}^{1} ]$$

can have an overlap time so that once the EMI-switch is turned-off after the completion of the charge interval, the load current has a path through the top switch.

During Transition D, the load-side pole voltage is tuned i.e., h_{L}: −1→0→1. Focusing on the three load-side gate signal waveforms of FIG. 15

$$G [ {S}_{L}^{1} ] , G [ {S}_{L}^{0} ] , G [ {S}_{L}^{- 1} ] ,$$

the transition occurs from the top transistor to the EMI-E switch

$$( {S}_{L}^{0} )$$

to the bottom diode (due to load current direction out of the pole.

As soon as the gate signal

$$G [ {S}_{L}^{1} ]$$

goes to zero, the sun current will turn-on the bottom diode (similar to the conventional case) if the EMI-E switch is not activated. In order to avoid this conventional scenario and tune the dv/dt edge, an overlap time is introduced between

$$G [ {S}_{L}^{1} ] and G [ {S}_{L}^{0} ] .$$

As soon as

$$G [ {S}_{L}^{1} ]$$

is made zero, EMI-switch

$${S}_{L}^{0}$$

takes over the current I_{L} and begins to discharge the tiny capacitor. The bottom switch diode cannot conduct because it is reverse-biased (the voltage across the diode is V_{C-tiny}>0). The discharge interval t_{D} is tuned to discharge the tiny capacitor to 0V after which the bottom switch diode takes over. The bottom switch can now be turned-on after a DT.

The bottom three waveforms of FIG. 15 illustrate voltage, current and power waveforms of the load-side bottom switch. In contrast to the conventional case, the dv/dt edges of the voltage waveform are tuned using the EMI-circuitry. Hence, they can be designed (to reduce EMI noise) and are not determined by the inherent and fast rising and falling edges of the transistor devices. Further, the designed modulation strategy features near zero voltage when the current rises/falls. Hence, the switching losses are close to zero, as illustrated by the bottom waveform.

In certain embodiments, a tiny capacitor can be used to tune the dv/dt edges. The pole voltages map the dv/dt edges of the tiny capacitor to suppress EMI noise and introduce ZVS operation. The tiny capacitor needs to be charged and hence needs a net current flowing into the capacitor. Further, within the switching frequency period, the tiny capacitor needs to be discharged and hence needs a net current flowing out of the capacitor (Cdv/dt=i, when i>0, dv>0 and when i<0, dv<0).

In certain embodiments, if the current transition happens from a transistor to a diode through the EMI-E switch, the EMI-E switch gate signal has overlap (OL) interval with the transistor gate signal and has a DT interval with the transistor gate signal where the diode first starts to conduct. Similarly, if the current transition happens from a diode to a transistor through the EMI-E switch, the EMI-E switch gate signal first has a DT interval with the transistor gate signal where the diode first starts to conduct and then an OL interval with the transistor gate signal. This prevents shoot-through and over-voltage scenarios.

During the dv/dt transitions when both source & load edges are tuned, if it is a charge interval, source-side signals are activated prior to the load side intervals (see, e.g., FIG. 15). If it is a discharge interval, load-side signals are activated prior to the source-side intervals (see, e.g., FIG. 12).

In certain embodiments, the capacitor voltage (v_{C}) and the capacitor current (i_{C}) are related to each other by

$$C \frac{{dv}_{C}}{dt} = {i}_{C} \qquad ( 3 )$$

where C is the capacitance value. This equation can be used to estimate the size of the tiny capacitor. Using first order approximations:

$${C}_{tiny} \frac{Δ v}{Δ t} = {i}_{C} ⇒ {C}_{tiny} = {I}_{C} \frac{{t}_{C / D}}{{V}_{C - Link}} \qquad ( 4 )$$

where, t_{C/D} represent the tunable charge/discharge time. Typical 650V MOSFET devices switch at <100 ns. Assuming that the EMI noise is reduced by 20 dB (or an order of magnitude), t_{C/D}≈1 μs. For a 400V dc bus system (i.e., V_{C-Link}≈400V),

$${C}_{tiny} \approx {I}_{C} \frac{1 µs}{400} . \qquad ( 5 )$$

Here, I_{C}=I_{S}, I_{C}=I_{L}, I_{C}=I_{S}−I_{L} or I_{C}=I_{L}−I_{S} based on buck/boost operation and rising or falling dv/dt edge. For low power systems (smaller current values), the capacitance value will be smaller. For example, for a 3 kW system, C_{tiny} would be 1-10s of nano-farads. For a 300 W system, C_{tiny} would be fractions of nano-farads. Similarly, for a higher power system, say 30 KW, C_{tiny} would be 100s of nano-farad.

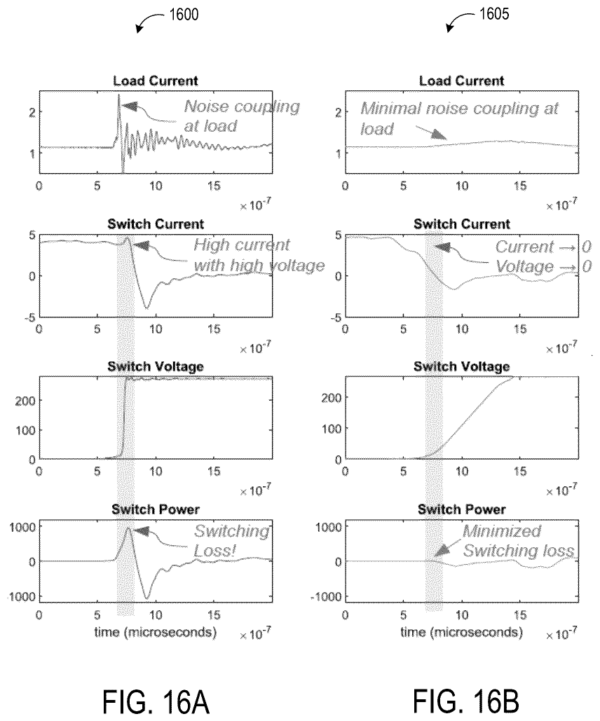

FIG. 16 illustrates an example of experimental data confirming feasibility of the disclosed approach while illustrating reduced EMI noise issues and minimized switching losses 1600. The example 1600 includes experimental results from a buck converter prototype running at 250 W, featuring a tiny capacitor of 5.4 nF and V_{C-Link}≈280V. The waveforms are as follows: load current waveform, source-side bottom switch voltage, current and power waveform. The scenarios are similar to the tiny capacitor rising edge of FIGS. 11 and 12 with the conventional and disclosed approach (respectively corresponding to the first star intervals).

In conventional modulation, the switch turn-off time is characterized by the inherent transition times. With the disclosed modulation approach, the switch turn-off time can be tuned to ≈1 μs. The reduction in EMI noise is clearly evident from the top load current waveform which sees noise coupling with the conventional approach. In contrast, with the disclosed modulation strategy, the load current sees minimal high-frequency noise with much smaller amplitude.

In the example 1600, the switch current is measured using a sense-resistor. Due to the relatively high EMI noise in the conventional case, the conventional waveform is noisier than the disclosed approach waveform. The waveforms represent filtered results of the switch current turning-off from about 4 A to 0 A.

In the example 1600, the switch voltage is measured using a high bandwidth single-ended passive probe. In the conventional case, the switch voltage rises at a fast rate, dictated by the switch design (≈50 ns). In the disclosed case, the switch voltage rise is tuned to be ≈1 μs.

In the example 1600, multiplication of the switch voltage and current waveform can provide an estimate of the instantaneous switching losses. In the conventional case, as illustrated by FIG. 11, the switch current is high at the instant of high switch voltage resulting in switch power losses. In the disclosed case, the switch current is close to 0 A when the switch voltage begins to rise resulting in minimal switching power losses.

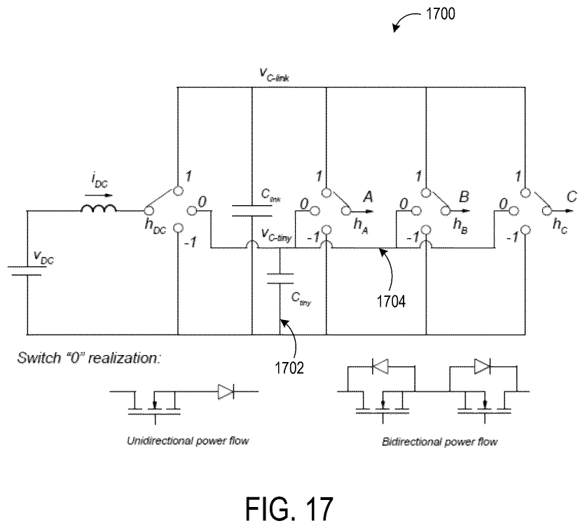

FIG. 17 illustrates an example of a circuit schematic for DC-AC power conversion 1700. Such topology is commonly found in transformer-less photovoltaic systems and traction applications, for example. In the example, traces 1702, 1704 highlight the addition of the throw to the DC and AC side switches. The throws can be realized, for example, using a transistor and a diode or two transistors for unidirectional and bidirectional power flow, respectively. While the additional devices may be rated for the full dc-link voltage, the current rating is expected to be minimal since time intervals t_{C} and t_{D} are expected to be <1 μs.

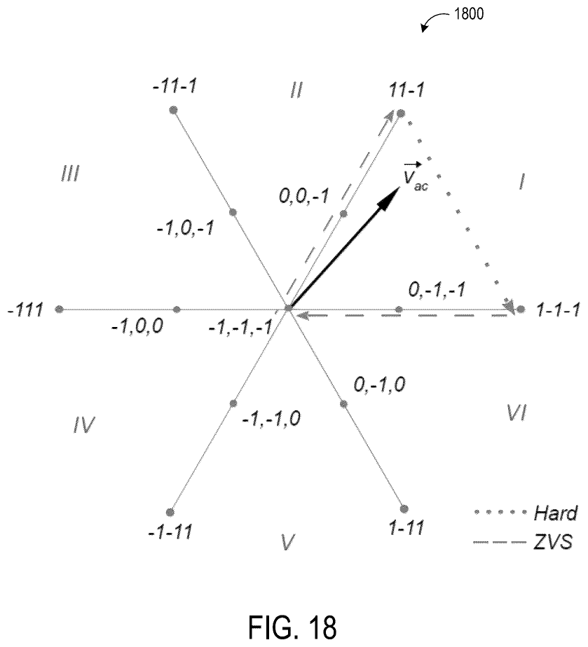

FIG. 18 illustrates an example of a space vector diagram for an AC inverter operation 1800 in accordance with certain embodiments of the disclosed technology. In the example, the AC phase A is aligned with the horizontal x-axis of the diagram and the AC vector

$${v}_{a c}^{\to }$$

is shown in Sector I of operation. In addition to the conventional space vectors illustrated on the outer edges with states “1” and “−1”, the figure also illustrates the disclosed space vectors with “0” state.

Considering conventional operations, during sector I, the nearest space vectors [11-1] and [1-1-1] are typically selected. With the disclosed approach, additional space vectors with “0” state are appended during the beginning and the end of the active space vectors. For example, during sector I, the state vector sequence can be [−1-1-1]→[0-1-1]→[1-1-1]→[11-1]→[00-1]→[−1-1-1]. The transition between several state vectors is also highlighted in the figure using dotted and dashed arrow lines. The state vector transition on the outer edge is under hard switching condition, also shown by the dotted line. In contrast, the remaining transitions have been tuned for low dv/dt rate and ZVS operation. The space vector transitions can be clockwise or counterclockwise and are based on minimizing DC link capacitor voltage ripple, reactive power minimization, loss minimization, etc.

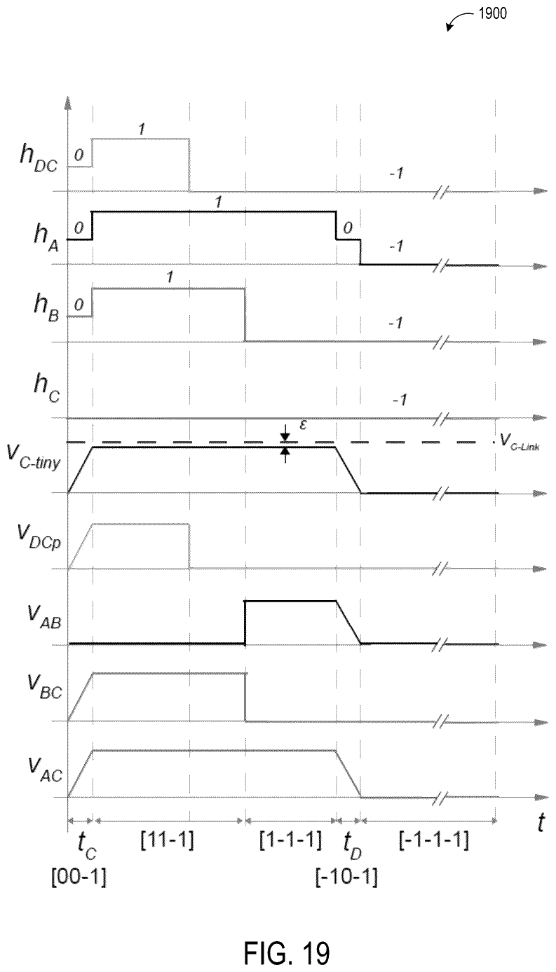

FIG. 19 illustrates an example of switching waveforms for DC-AC conversion for a certain sector of operation 1900. The figure details the addition of the switch state “0” with the DC and AC phases where the “0” state is appended during the beginning or the end of the switching functions (h). The figure also illustrates the AC line-line voltages. It may be observed that four out of the six switching transitions have been selected to be tuned by utilizing the C_{tiny} capacitor. The DC switching state is sequenced with the first active AC state vector to charge the tiny capacitor C_{tiny}. Similar analysis can be extended for the remaining sectors of the space vector diagram.

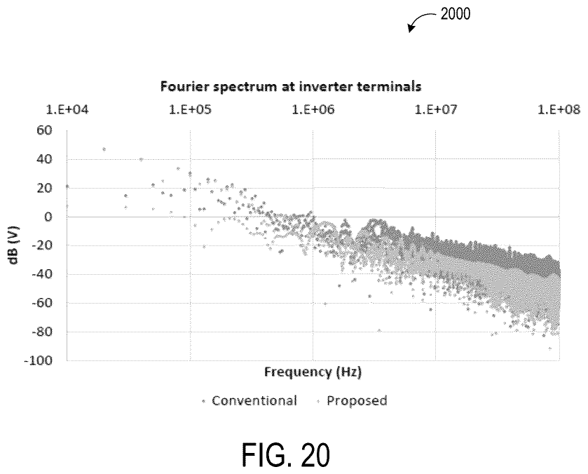

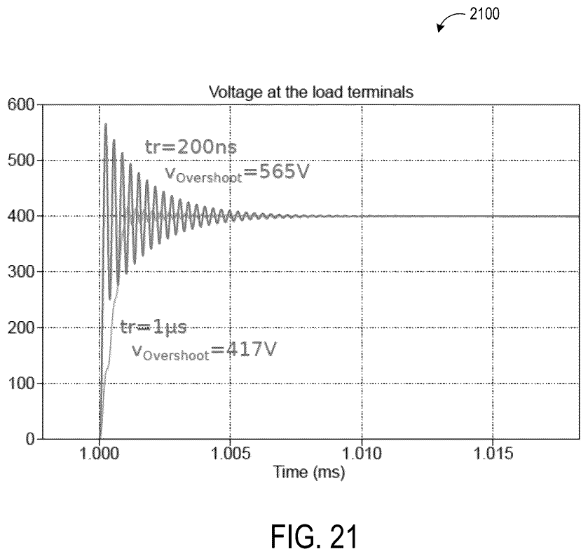

In an example, results from a DC-AC converter design are presented. The design parameters include power throughput P=3 kW, dc voltage V_{DC}=200V, ac voltage V_{AC}=208V with 60 Hz output frequency, dc-link voltage V_{C-link}=400V and f_{SW}=20 kHz. With the design choice values of the charge and the discharge time intervals to be ≈1 μs, C_{tiny} is sized to be 20 nF. Detailed simulation models have been developed in PLECS circuit simulator environment. FIGS. 20-21 detail the comparison between the conventional approaches and the disclosed PWM approaches.

FIG. 20 illustrates an example of a Fourier spectrum at inverter terminals with conventional approaches and disclosed approaches 2000, and FIG. 21 illustrates an example of switching voltage transient at load terminals with conventional approaches and disclosed approaches 2100. FIG. 20 compares the Fourier spectrum of the inverter terminal voltages where the disclosed PWM approach results in reduced electromagnetic noise due to significantly reduced dv/dt rate, without any increase in losses. While FIG. 20 illustrates the results at the inverter terminals, the load may be connected to the inverter with long cables. High dv/dt transitions can cause significant voltage overshoots due to cable parasitics. FIG. 21 compares the switching voltage transient at the load terminals between the conventional and the disclosed PWM method when the load is connected to the inverter with a 10 ft long cable. The results clearly illustrate the high voltage over-shoot due to cable parasitics (where, cable inductance is 0.25 μH/ft and capacitance is 100 pF/ft) in the conventional case where the voltage over-shoots can be >40%. The disclosed approach limits the voltage overshoot to <4.5%.

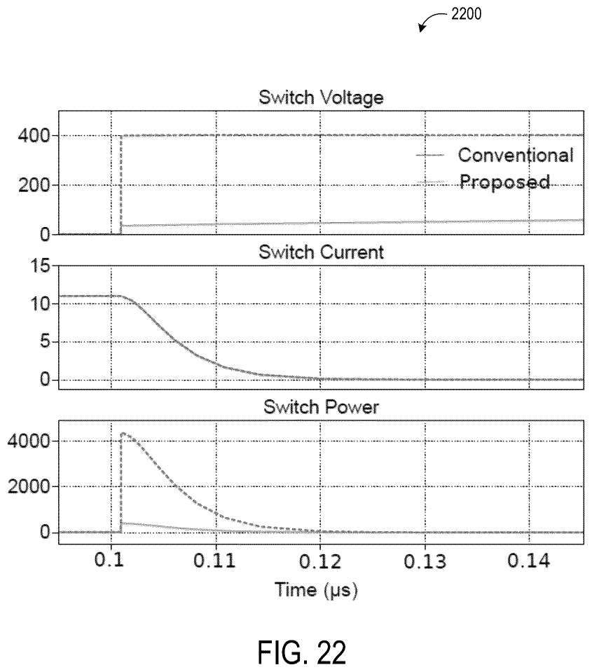

FIG. 22 illustrates an example of a switch turn-off transition with conventional approaches and disclosed approaches 2200. The figure illustrates the switch voltage, current and power waveform with the conventional approaches and the disclosed PWM approaches. While the switch current decays with a fast transition time of 15 ns, the voltage transition is tuned to be ≈1 μs with the disclosed PWM approach. The overlap between the non-zero switch current and the switch voltage occurs when the switch voltage is still close to zero. The switching occurs under ZVS despite a slow transition time of ≈1 μs resulting in reduced switch losses, also confirmed by the switch power waveform.

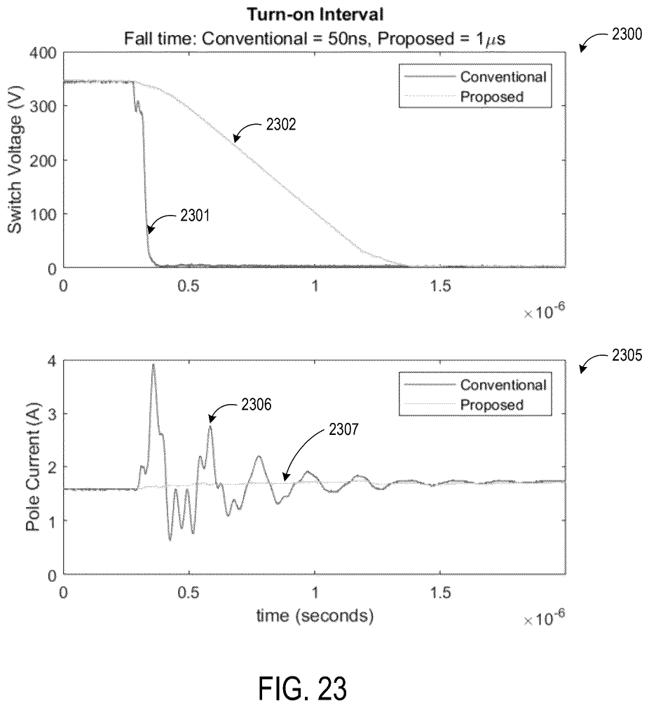

FIG. 23 illustrates an example 2300 of experimental waveforms of the turn-on interval switch voltage with conventional approaches (2301) and disclosed PWM approaches (2302). FIG. 23 also illustrates an example 2305 of experimental waveforms of the turn-on interval pole current with conventional approaches (2306) and disclosed PWM approaches (2307).

The switch voltage fall time is ~50 nanoseconds as observed in waveform 2301. In contrast, the voltage fall time i.e., dv/dt rate is tuned to ~1 micro-second. Due to the noisy dv/dt rate in the conventional case, the pole current is very noisy; that is, high-frequency ringing is observed when it should be constant value. The current waveform is very smooth (and nearly constant) in the disclosed case.

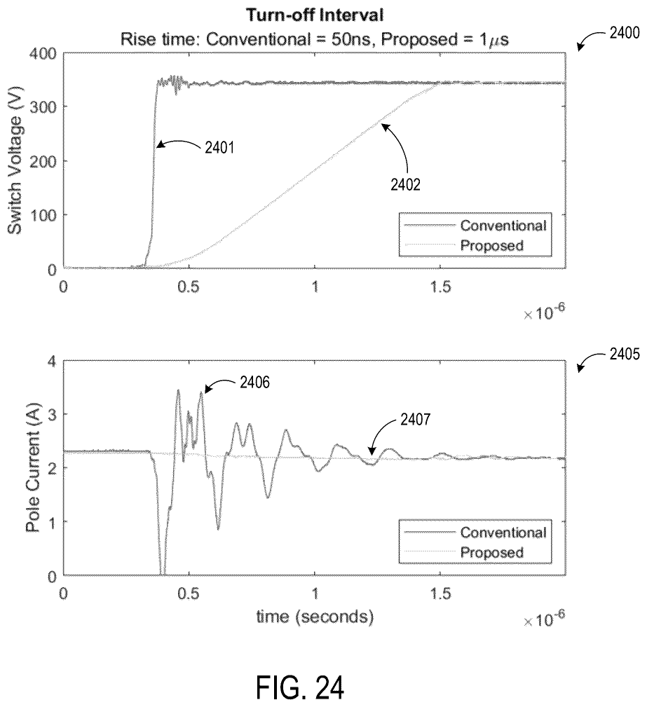

FIG. 24 illustrates an example 2400 of experimental waveforms of the turn-off interval switch voltage with conventional approaches (2401) and disclosed PWM approaches (2402). FIG. 24 also illustrates an example 2405 of experimental waveforms of the turn-off interval pole current with conventional approaches (2406) and disclosed PWM approaches (2407).

The switch voltage rise time is ~50 nanoseconds as observed in the waveform 2401. In contrast, the voltage rise time i.e., dv/dt rate is tuned to ~1 micro-second. Again, due to the noisy dv/dt rate in the conventional case, the pole current is very noisy; that is, high-frequency ringing is observed when it should be constant value. The current waveform is very smooth (and nearly constant) in the disclosed case.

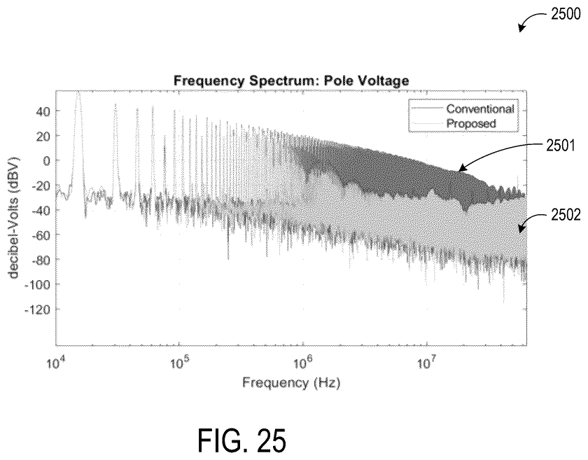

FIG. 25 illustrates an example 2500 of the frequency-domain Fourier spectrum of the switch voltage (illustrated by FIG. 5) for conventional approaches (2501) and disclosed approaches (2502). The figure illustrates that, in the disclosed case, the spectrum is less noisy than in the conventional case.

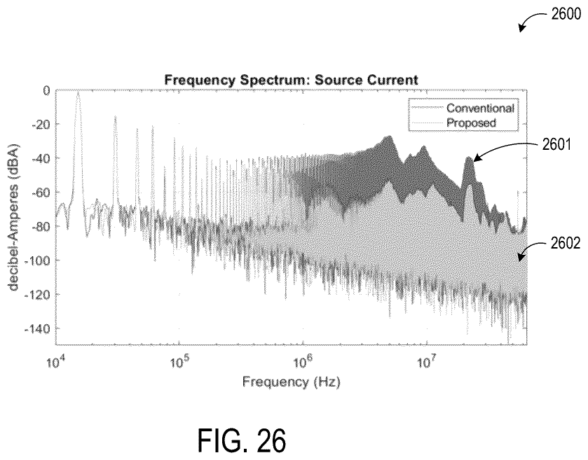

FIG. 26 illustrates an example 2600 of the frequency-domain Fourier spectrum of the pole current (of FIGS. 23-24) for conventional approaches (2601) and disclosed approaches (2602). The figure illustrates that, in the disclosed case, the spectrum is less noisy than in the conventional case.

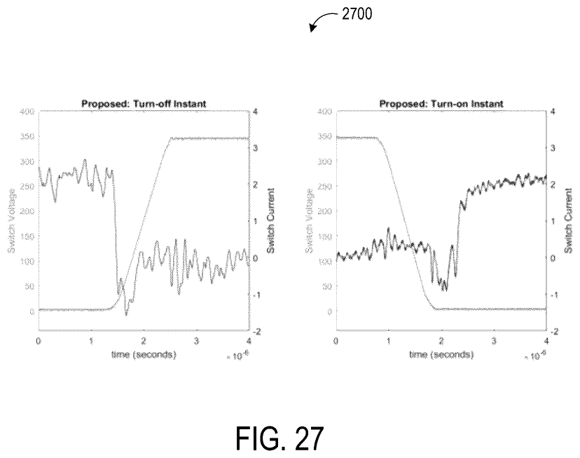

FIG. 27 illustrates experimental results 2700 that confirm the analytical results illustrated by FIG. 6B. During each of the transitions, the switching losses are negligible since voltage is close to zero when current is zero. High-voltage and high-current overlap interval is negligible.

The description of embodiments has been presented for purposes of illustration and description. Suitable modifications and variations to the embodiments may be performed in light of the above description or may be acquired from practicing the methods. The methods may be performed by executing stored instructions with one or more logic devices (e.g., processors) in combination with one or more hardware elements, such as storage devices, memory, hardware network interfaces/antennas, switches, actuators, clock circuits, and so on. The described methods and associated actions may also be performed in various orders in addition to the order described in this application, in parallel, and/or simultaneously. The described systems are exemplary in nature, and may include additional elements and/or omit elements. The subject matter of the present disclosure includes all novel and non-obvious combinations and sub-combinations of the various systems and configurations, and other features, functions, and/or properties disclosed.

As used herein, the terms “system” or “module” or “modulator” may include a hardware and/or software system that operates to perform one or more functions. For example, a module or system may include a computer processor, controller, or other logic-based device that performs operations based on instructions stored on a tangible and non-transitory computer readable storage medium, such as a computer memory. Alternatively, a module or system may include a hard-wired device that performs operations based on hard-wired logic of the device. Various modules or units shown in the attached figures may represent the hardware that operates based on software or hardwired instructions, the software that directs hardware to perform the operations, or a combination thereof.

The foregoing described aspects depict different components contained within, or connected with different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

As used in this application, an element or step recited in the singular and proceeded with the word “a” or “an” should be understood as not excluding plural of said elements or steps, unless such exclusion is stated. Furthermore, references to “one embodiment” or “one example” of the present disclosure are not intended to be interpreted as excluding the existence of additional embodiments that also incorporate the recited features. The terms “first,” “second,” “third,” and so on are used merely as labels, and are not intended to impose numerical requirements or a particular positional order on their objects. The following claims particularly point out subject matter from the above disclosure that is regarded as novel and non-obvious.

1. A power electronic circuit, comprising:
a first switch;
a second switch; and
a capacitor, wherein a switch throw of the first switch is configured to be electrically coupled to a first terminal of the capacitor and a switch throw of the second switch is configured to be electrically coupled to a second terminal of the capacitor, wherein the first and second switches are configured to connect to the capacitor periodically every switching cycle.

2. The power electronic circuit of claim 1, wherein the first switch is a source switch for a source.

3. The power electronic circuit of claim 2, wherein the second switch is a load switch for a load.

4. The power electronic circuit of any one of claim 3, wherein a voltage transfer relationship between the source and the load is determined by at least a width of a switching function of the source.

5. The power electronic circuit of any one of claim 3, wherein a voltage transfer relationship between the source and the load is determined by at least a width of a switching function of the load.

6. The power electronic circuit of any one of claim 3, wherein a current transfer relationship between the source and the load is determined by at least a width of a switching function of the source.

7. The power electronic circuit of any one of claim 3, wherein a current transfer relationship between the source and the load is determined by at least a width of a switching function of the load.

8. The power electronic circuit of any one of claim 1, wherein the capacitor is a tiny capacitor.

9. The power electronic circuit of any one of claim 1, wherein the power electronic circuit is a DC-DC converter.

10. The power electronic circuit of any one of claim 1, wherein the power electronic circuit is a DC-AC converter.

11. A power electronic circuit, comprising:
a first switch;
a second switch; and
an electromagnetic interference (EMI) eradication circuit electrically coupled between the first switch and the second switch, the EMI eradication circuit including:
a first bidirectional transistor electrically coupled with the first switch;
a second bidirectional transistor electrically coupled with the second switch; and
a capacitor electrically coupled between the first bidirectional transistor and the second bidirectional transistor.

12. The power electronic circuit of claim 11, wherein the EMI eradication circuit includes a common source and a common gate.

13. The power electronic circuit of claim 11, wherein the EMI eradication circuit includes a common source and separate gates.

14. The power electronic circuit of any one of claim 11, wherein the EMI eradication circuit includes a common drain and separate gates.

15. The power electronic circuit of any one of claim 11, wherein the first switch is a source switch for a source.

16. The power electronic circuit of any one of claim 15, wherein the second switch is a load switch for a load.

17. The power electronic circuit of any one of claim 11, wherein the capacitor is a tiny capacitor.

18. The power electronic circuit of any one of claim 17, wherein the tiny capacitor is used to tune dv/dt edges.

19. The power electronic circuit of any one of claim 11, wherein, during dv/dt transitions when source and load edges are tuned and it is a charge interval, source-side signals are activated prior to load-side intervals.

20. The power electronic circuit of any one of claim 11, wherein, during dv/dt transitions when source and load edges are tuned and it is a discharge interval, load-side signals are activated prior to source-side intervals.
